(19) United States
(12) Patent Application Publication
(10) Pub. No.: US 2024/0097076 A1
(43) Pub. Date: Mar. 21, 2024

(54) DISPLAY PANEL, MANUFACTURING METHOD OF DISPLAY PANEL, AND DISPLAY DEVICE

(71) Applicant: Tianma Advanced Display Technology Institute (Xiamen) Co., Ltd., Xiamen (CN)

(72) Inventor: Xiaoli Liu, Xiamen (CN)

(73) Assignee: Tianma Advanced Display Technology Institute (Xiamen) Co., Ltd., Xiamen (CN)

(21) Appl. No.: 18/526,785

(22) Filed: Dec. 1, 2023

(30) Foreign Application Priority Data
Sep. 28, 2023 (CN) 202311277273.6

(51) Int. Cl. H01L 33/44; H01L 25/075; H01L 25/16

(52) U.S. Cl. CPC H01L 33/44; H01L 25/0753; H01L 25/167; H01L 2933/0025

(57) ABSTRACT

Provided are a display panel, a manufacturing method thereof, and a display device. The display panel includes a display region and a non-display region. The display panel includes a light-shielding layer and a bank. The light-shielding layer includes a part located in the display region. The bank is located in the non-display region and in contact with the light-shielding layer.

### CROSS-REFERENCE TO RELATED APPLICATIONS

This application claims priority to Chinese patent application No. 202311277273.6 filed with the China National Intellectual Property Administration (CNIPA) on Sep. 28, 2023, the disclosure of which is incorporated herein by reference in its entirety.

### TECHNICAL FIELD

The present disclosure relates to the field of display technologies and, in particular, to a display panel, a manufacturing method of a display panel, and a display device.

### BACKGROUND

In the related art, the light-shielding material is generally provided in the display region of a display panel to reduce the reflectivity of the display region.

At present, the preparation technique of the light-shielding material is not yet mature, and multiple routings exist.

### SUMMARY

The present disclosure provides a display panel, a manufacturing method of a display panel, and a display device to improve the preparation effect of the light-shielding material.

The present disclosure provides a display panel. The display panel includes a display region and a non-display region. The display panel includes a light-shielding layer and a bank. The light-shielding layer includes a part located in the display region. The bank is located in the non-display region and in contact with the light-shielding layer.

The present disclosure further provides a manufacturing method of a display panel. The method includes providing a motherboard, where the motherboard includes at least one basic display panel, and each basic display panel includes a display region and a non-display region; forming a bank in the non-display region of each basic display panel; and forming a light-shielding layer on each basic display panel, where the light-shielding layer includes a part located in the display region and is in contact with the bank.

Based on the same inventive concept, the present disclosure further provides a display device. The display device includes any of the preceding display panels.

### BRIEF DESCRIPTION OF DRAWINGS

The drawings described herein, which are incorporated in the specification and form part of the specification, illustrate embodiments of the present disclosure and are intended to explain the principles of the present disclosure together with the description of the drawings.

To illustrate technical schemes in the embodiments of the present disclosure or in the related art more clearly, the drawings used in the description of the embodiments or the related art are briefly described below. Apparently, those of ordinary skill in the art may obtain other drawings based on the drawings described below on the premise that no creative work is done.

FIG. 1 is a schematic diagram of the overall planar structure of a display panel according to an embodiment of the present disclosure;

FIG. 2 is a partial cross-sectional view of a display panel according to an embodiment of the present disclosure;

FIG. 3 is a partial cross-sectional view of another display panel according to an embodiment of the present disclosure;

FIG. 4 is a partial cross-sectional view of another display panel according to an embodiment of the present disclosure;

FIG. 5 is a partial cross-sectional view of another display panel according to an embodiment of the present disclosure;

FIG. 6 is a partial cross-sectional view of another display panel according to an embodiment of the present disclosure;

FIG. 7 is a partial cross-sectional view of another display panel according to an embodiment of the present disclosure;

FIG. 8 is a partial cross-sectional view of another display panel according to an embodiment of the present disclosure;

FIG. 9 is a partial cross-sectional view of another display panel according to an embodiment of the present disclosure;

FIG. 10 is a schematic diagram of the overall planar structure of another display panel according to an embodiment of the present disclosure;

FIG. 11 is a schematic diagram of part of the planar structure of a display panel according to an embodiment of the present disclosure;

FIG. 12 is a schematic diagram of part of the planar structure of another display panel according to an embodiment of the present disclosure;

FIG. 13 is a schematic diagram of the planar structure of a bank according to an embodiment of the present disclosure;

FIG. 14 is a schematic diagram of part of the planar structure of another display panel according to an embodiment of the present disclosure;

FIG. 15 is a schematic diagram of the planar structure of a pixel region according to an embodiment of the present disclosure;

FIG. 16 is a partial cross-sectional view of a pixel region according to an embodiment of the present disclosure;

FIG. 17 is a schematic diagram of part of the planar structure of another display panel according to an embodiment of the present disclosure;

FIG. 18 is a partial cross-sectional view of another display panel according to an embodiment of the present disclosure;

FIG. 19 is a partial cross-sectional view of another display panel according to an embodiment of the present disclosure;

FIG. 20 is a partial cross-sectional view of another display panel according to an embodiment of the present disclosure;

FIG. 21 is a partial cross-sectional view of another display panel according to an embodiment of the present disclosure;

FIG. 22 is a partial cross-sectional view diagram of another display panel according to an embodiment of the present disclosure;

FIG. 23 is a partial cross-sectional view of another display panel according to an embodiment of the present disclosure;

FIG. 24 is a partial cross-sectional view of another display panel according to an embodiment of the present disclosure;

FIG. 25 is a partial cross-sectional view of another display panel according to an embodiment of the present disclosure;

FIG. 26 is a partial cross-sectional view of another display panel according to an embodiment of the present disclosure;

FIG. 27 is a partial cross-sectional view of another display panel according to an embodiment of the present disclosure;

FIG. 28 is a partial cross-sectional view of another display panel according to an embodiment of the present disclosure;

FIG. 29 is a partial cross-sectional view of another display panel according to an embodiment of the present disclosure;

FIG. 30 is a schematic diagram of part of the planar structure of another display panel according to an embodiment of the present disclosure;

FIG. 31 is a schematic diagram of the planar structure of an electronic device according to an embodiment of the present disclosure;

FIG. 32 is a flowchart of a manufacturing method of a display panel according to an embodiment of the present disclosure;

FIG. 33 is a partial cross-sectional view of a motherboard according to an embodiment of the present disclosure;

FIG. 34 is a partial cross-sectional view of another motherboard according to an embodiment of the present disclosure;

FIG. 35 is a partial cross-sectional view of another motherboard according to an embodiment of the present disclosure;

FIG. 36 is a partial cross-sectional view of a basic display panel according to an embodiment of the present disclosure;

FIG. 37 is a partial cross-sectional view of another basic display panel according to an embodiment of the present disclosure;

FIG. 38 is a partial cross-sectional view of another basic display panel according to an embodiment of the present disclosure; and

FIG. 39 is a partial cross-sectional view of another basic display panel according to an embodiment of the present disclosure.

### DETAILED DESCRIPTION

For a better understanding of the preceding object, features, and advantages of embodiments of the present disclosure, schemes of the embodiments of the present disclosure are further described below. It is to be noted that if not in collision, the embodiments of the present disclosure and features therein may be combined with each other.

Many details are set forth in the following description for a full understanding of the embodiments of the present disclosure, and the embodiments of the present disclosure may be implemented in other manners not described herein. Apparently, the embodiments in the specification are part, not all, of the embodiments of the present disclosure.

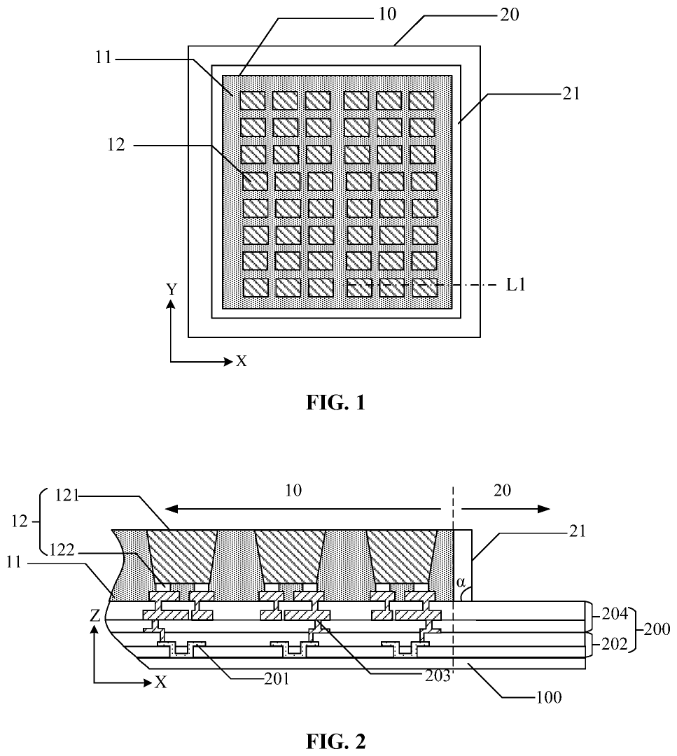

An embodiment of the present disclosure provides a display panel. As shown in FIGS. 1 and 2, (FIG. 1 is a schematic diagram of the overall planar structure of a display panel, and FIG. 2 is a partial cross-sectional view of a display panel taken along a cutting line L1 in FIG. 1), the display panel includes a display region 10 and a non-display region 20. The display panel includes a light-shielding layer 11 and a bank 21 located in the non-display region 20, the light-shielding layer 11 includes a part located in the display region 10, and the bank 21 is in contact with the light-shielding layer 11.

The bank 21 is prepared on the display panel before the light-shielding layer 11. The light-shielding material is filled into the display region 10 of the display panel to form the light-shielding layer 11. The bank 21 plays a blocking role during the filling process of the light-shielding material to prevent the light-shielding material from entering the non-display region 20. Finally, the structure in which the bank 21 is in contact with the light-shielding layer 11 shown in FIGS. 1 and 2 is formed.

A side of the non-display region 20 facing away from the display region 10 includes a cutting edge of the display panel. During production and manufacturing, multiple display panels are usually manufactured simultaneously on a motherboard, and the motherboard is finally cut and separated into multiple display panels. In the display panel provided in the present disclosure, through the bank, the light-shielding material can be blocked, the edge position of the light-shielding layer formed by the light-shielding material can be limited, and the light-shielding material is limited in the display region so that the light-shielding material does not further overflow to the region where the cutting edge is located, and the light-shielding material is prevented from adhering to a cutting wheel or from affecting cutting laser transmittance, thereby ensuring smooth subsequent processes and cutting.

In an embodiment, as shown in FIGS. 1 and 2, the display panel further includes light-emitting elements 12 in the display region 10. The light-emitting element 12 includes a body 121 and an electrode 122. The light-emitting element 12 is connected to a driver layer 200 through the electrode 122. The body 121 may include a P-type semiconductor layer, an active layer, and an N-type semiconductor layer that are stacked. The preceding light-shielding material is filled between the light-emitting elements 12 during the preparation of the display panel and is also filled between the light-emitting elements 12 and the bank 21 to form the light-shielding layer 11 surrounding the light-emitting elements 12. The light-shielding layer 11 may be in contact with the sidewall of the light-emitting element 12 and may absorb the light emitted from the side surface of the light-emitting element 12.

As shown in FIG. 2, the display panel further includes a substrate 100 and the driver layer 200. The driver layer 200 is located on the substrate 100 and includes multiple thin-film transistors 201 corresponding to the light-emitting elements 12 as well as a first insulating layer 202, a metal layer 203, and a second insulating layer 204. The light-emitting elements 12 are electrically connected to the thin-film transistors 201 through the metal layer 203.

The first insulating layer 202 and the second insulating layer 204 may include an organic insulation material or an inorganic insulation material, without excessive limitations here. The substrate may include materials such as glass, quartz, and polymer resins.

It is to be noted that the first insulating layer 202, the metal layer 203, and the second insulating layer 204 may each be a structure including multiple stacked insulation material layers shown in FIG. 2. It is to be noted that, to keep the drawings concise and clear, the first insulating layer 202 and the second insulating layer 204 in the drawings of the following embodiments are simply shown as single-layer structures, which is not intended to limit the first insulating layer 202 and the second insulating layer 204 to be single-layer structures, and for a specific stacked structure, reference may be made to the embodiment shown in FIG. 2.

The preceding light-emitting element 12 is a light-emitting diode (LED). For example, the light-emitting element 12 is an inorganic LED. The light-emitting elements 12 may be prepared separately and bonded to the electrodes in the driver layer 200 through transport to achieve the electrical connection between the light-emitting elements 12 and the driver layer 200.

In the related art, to reduce the reflectivity of the metal circuit at the bottom of the display region of the display panel and improve the halo and crosstalk, the light-shielding layer is usually built into the driver layer 200, that is, one light-shielding layer is formed during the preparation stage of the driver layer 200. When the light-shielding layer is generated during the preparation stage of the driver layer 200, the region for placing the light-emitting elements needs to be reserved, making it unsuitable for a display panel with a high pixel density and making it impossible to ensure that the light-shielding layer completely covers the bottom circuits of the light-emitting elements. However, the light-shielding layer in the preceding embodiments of the present disclosure is formed by filling and can cover the bottom of the LEDs, thereby avoiding the impact of external light on the performance of the bottom circuits and thin-film transistors and improving the leakage current and flicker.

Although in the preceding embodiments of the present disclosure, the light-shielding layer does not need to be generated when the driver layer of the display panel is prepared, the preceding embodiments can also be used for the display panel in which the driver layer already includes the light-shielding layer, that is, the display panel includes both the light-shielding layer in the driver layer and another light-shielding layer surrounding the light-emitting elements in the preceding embodiments, thereby better reducing the reflectivity of the metal circuits and improving the halo and crosstalk.

In some embodiments, the material of the bank includes a light-transmissive material.

The light-transmissive material is used to make the bank so that the light transmittance can be improved and the display effect of the display panel can be optimized.

The light transmittance of the light-transmissive material may be greater than 70%, and the material includes, but is not limited to, acrylic resin, epoxy resin, polysiloxane, polycarbonate, and other organic materials as well as a mixture of the preceding materials.

It is to be noted that the preceding embodiments do not limit all structures made of the light-transmissive material in the non-display region of the display panel to be the bank. The region of the bank facing away from the display region may also be filled with the light-transmissive material, to bridge the step difference between the light-emitting elements or other structures and the driver layer. Moreover, compared with the light-shielding layer made of the light-shielding material, the light-transmissive material has stronger adhesion to the display panel. Filling the outermost layer of the display panel with the light-transmissive material is conducive to preventing external water vapor from entering the display region.

In some embodiments, as shown in FIG. 2, the sidewall of the bank 21 does not include a step, that is, the bank 21 is made of a single material through one etching process, rather than multiple etching processes, and the bank 21 is not formed by stacking multiple layers of materials.

In some embodiments, as shown in FIG. 2, the included angle α between the sidewall of the bank 21 and the bottom surface of the bank 21 is in the range between 85° and 95°. In an embodiment, the included angle α is 90°, that is, the bank 21 is made of a single material through one etching process, rather than multiple etching processes, and the bank 21 is not formed by stacking multiple layers of materials.

In other embodiments, considering different properties of different materials during etching, the included angle α between the sidewall of the bank 21 and the bottom surface of the bank 21 is in the range between 80° and 95°.

In some embodiments, as shown in FIG. 2, the bank 21 is a single-layer structure, that is, the bank 21 is made of a single material through one etching process, rather than multiple etching processes, and the bank 21 is not formed by stacking multiple layers of materials.

Compared with a bank formed by stacking multiple layers of films, the bank 21 is formed using a single-layer structure so that the optical loss can be reduced and higher light transmittance can be achieved. In addition, the bank formed by stacking multiple layers of films generally requires multiple etching processes. Considering that process errors exist in the etching of each film, the width of the bank formed by stacking multiple layers of films is relatively large, while a single-layer bank structure provided in the present disclosure may have a relatively small width.

To more clearly reflect the function of the bank 21 in blocking the material of the light-shielding layer, as shown in FIG. 2, the width of the bank 21 in the X direction is less than the height of the bank 21 in the Z direction. However, in some embodiments, the width of the bank 21 in the X direction is greater than or equal to the height of the bank 21 in the Z direction, thereby ensuring the structural stability of the bank 21 and facilitating production and manufacturing. The width of the bank 21 may be understood as a length of the bank 21 in the direction from the display region 10 to the non-display region 20.

In some embodiments, as shown in FIG. 2, the upper surface of the bank 21 in the Z direction is flush with the upper surface of the light-emitting element 12. The upper surface of the bank 21 refers to a surface on a side of the bank 21 facing away from the driver layer 200, and the upper surface of the light-emitting element 12 refers to a surface on a side of the light-emitting element 12 facing away from the driver layer 200.

After the bank 21 is flush with the upper surface of the light-emitting element 12, the upper surface of the light-shielding layer 11 formed by filling the light-shielding material into the display region 10 of the display panel can also be flush with the upper surface of the bank 21 and the upper surface of the light-emitting element 12, thereby bridging the step difference between the light-emitting elements and the driver layer of the display panel, ensuring that the light-shielding layer 11 completely surrounds the light-emitting elements 12, and improving the halo and crosstalk.

It should be understood that the upper surfaces of the two are flush, which represents that in the thickness direction (the Z direction shown in FIG. 2) of the display panel, the two may have a height difference within the process error range. The process error range is determined according to the actual manufacturing process accuracy. For example, during the implementation, if the minimum process accuracy when generating the corresponding structure is 0.1 μm, the process error range may be set to ±0.1 μm or +0.2 μm; if the minimum process accuracy when generating the bank is 1 μm, the process error range may be set to ±1 μm or ±2 μm. The basic flushing and the process error range in the following embodiments are similar to those described here and are not repeated.

In some embodiments, the height of the bank is greater than or equal to 10 μm.

The light-emitting element in the preceding embodiments is the LED, and the height of the light-emitting element in the thickness direction of the display panel is usually greater than or equal to 10 μm. To make the upper surface of the bank flush with the upper surface of the light-emitting element, the height of the bank needs to be greater than or equal to 10 μm.

In some embodiments, the width of the bank is greater than or equal to 10 μm.

The bank needs to have a certain width, thereby ensuring the structural stability of the bank and facilitating production and manufacturing.

In some embodiments, the material of the light-shielding layer includes a black organic material.

The light transmittance of the black organic material is approximately 0%, and the material includes, but is not limited to, acrylic resin doped with carbon black or black pigment, epoxy resin doped with carbon black or black pigment, polysiloxane doped with carbon black or black pigment, polycarbonate doped with carbon black or black pigment, and other organic materials doped with carbon black or black pigment, as well as a mixture of the preceding materials.

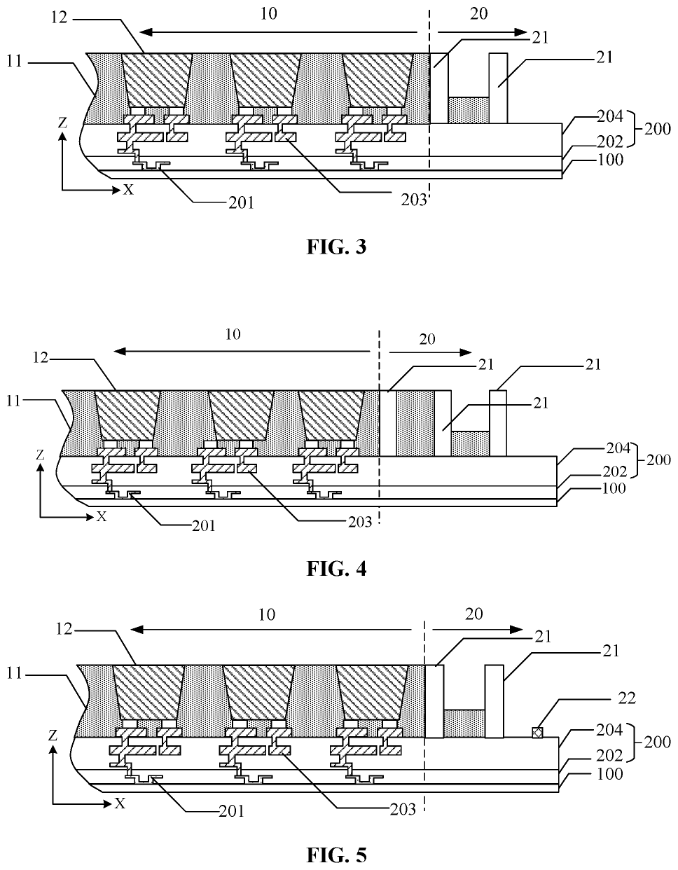

In some embodiments, as shown in FIG. 3, the display panel includes at least two banks 21, and the region between two adjacent banks 21 is configured to store an overflowing material of the light-shielding layer 11. In FIG. 3, the same filling pattern as that of the light-shielding layer 11 is used to represent the overflowing material of the light-shielding layer 11 between two banks 21. The same applies to the drawings of other embodiments of the present disclosure. The details are not repeated.

During the implementation, to ensure that the light-shielding layer 11 is completely filled into the display region, the amount of the prepared light-shielding material is usually slightly more than the actual required amount, causing the material to overflow from the range limited by a single bank. At least two banks are provided so that the light-shielding material overflowing from the display region can be stored, the edge position of the light-shielding material can be limited, and the light-shielding material does not further overflow to the region where the cutting edge is located, thereby further ensuring smooth subsequent processes and cutting.

In some embodiments, as shown in FIG. 3, the sidewall included angles of the at least two banks are substantially the same, that is, multiple banks are made through one etching process, rather than multiple etching processes separately. In the related art, for the bank structure formed by stacking multiple films, process errors exist in the etching pattern corresponding to each film, resulting in steps on the sidewall of the formed bank, and the shapes of the multiple banks are different. The multiple banks 21 in the present disclosure are formed through one etching process. The shapes of the multiple banks 21 are substantially the same, and the sidewall included angles of the multiple banks 21 are substantially the same.

In an embodiment, as shown in FIG. 4, the display panel includes three or more banks 21, the region between every two adjacent banks 21 forms an overflow groove, and each overflow groove is configured to store the overflowing material of the light-shielding layer 11 to effectively block the light-shielding material.

Further, since the amounts of the light-shielding material overflowing in different regions of the display panel are different, the light-shielding material in the region with a less amount may not completely cover the bottom of the overflow groove, resulting in different distances at which the light-shielding material overflows in different regions and thus, resulting in visually uneven edges of the display region. In the preceding embodiment, three or more banks (that is, two or more overflow grooves) are provided. Due to an increase in the number of overflow grooves and the limitation of the area of the non-display region, the lateral distance of each overflow groove is correspondingly shortened. If the amounts of the overflowing light-shielding material in two regions are not particularly different, the bottoms of the same number of overflow grooves can be completely covered, the distances at which the light-shielding material overflows in these two regions are the same, and the edge of the display region is visually even.

Moreover, in an embodiment, the light-shielding material is doped with carbon black or black pigment compared to the material of the bank, resulting in that the adhesion of the light-shielding material to the display panel is less than that of the material of the bank. After multiple banks are provided, the light-shielding material is sandwiched between the banks so that the contact area between the light-shielding material and the banks on two sides increases, thereby increasing the adhesion of the light-shielding material to the display panel and preventing warping. The concave-convex structure formed by multiple banks and multiple overflow grooves is also conducive to blocking external water vapor from entering the display region of the display panel.

In some embodiments, the display panel further includes an alignment mark. As shown in FIG. 5, the alignment mark includes a first alignment mark 22 located on a side of the bank 21 facing away from the display region 10. The shape of the alignment mark may include a cross, a triangle, a diamond, and other shapes having the marking function.

In the case where the display panel includes multiple banks 21, the first alignment mark 22 is located on a side of the bank 21 closest to the cutting edge facing away from the display region 10, that is, the first alignment mark 22 is the outermost alignment mark in the display panel and is usually used in the process after the light-shielding layer 11 is generated, such as the alignment of an exposure machine or mask and the substrate, the alignment of a testing machine and the substrate, and the alignment of a cutting machine and the substrate.

When the display panel is manufactured, the position of the alignment mark needs to be optically identified so as to determine the position of the display panel and produce and process each position of the display panel. If the material of the light-shielding layer overflows and covers the alignment mark, the alignment mark cannot be optically identified and the subsequent process cannot be completed. The bank is provided in front of the first alignment mark so that the material of the light-shielding layer can be prevented from overflowing to the region where the first alignment mark is located, thereby ensuring that the first alignment mark is effective.

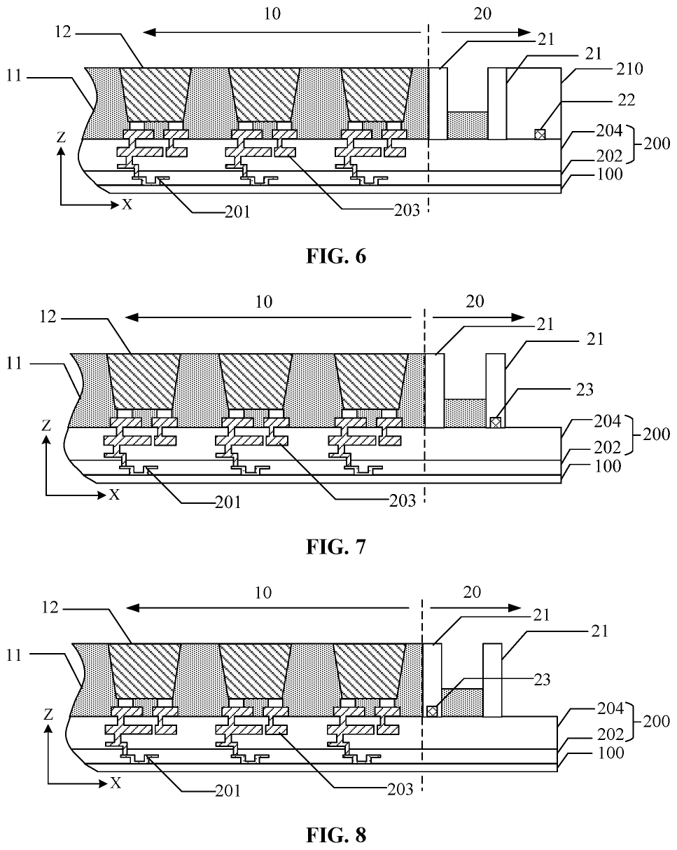

In an embodiment, as shown in FIG. 6, the light-transmissive material 210 may be used to cover the first alignment mark 22 on the basis of providing the bank, thereby further ensuring that the first alignment mark 22 is optically visible.

The material of the bank may be the light-transmissive material. The first alignment mark 22 may be generated before the process of generating the bank, and then during the process of generating the bank, the same light-transmissive material as the material of the bank is generated on a side of the first alignment mark 22 facing away from the substrate.

In some embodiments, as shown in FIGS. 7 and 8, the alignment mark includes a second alignment mark 23, and the bank 21 covers the second alignment mark 23.

The second alignment mark 23 may be configured to determine the position of a light-emitting element or a pixel in the display region during the problem-solving analysis of the display panel. Therefore, the second alignment mark 23 is located relatively close to the display region in the non-display region, and the bank needs to be provided to cover the second alignment mark, thereby preventing the light-shielding layer 11 or the overflowing material of the light-shielding layer 11 from covering the second alignment mark and causing the second alignment mark to be invalid.

The material of the bank covering the second alignment mark is the light-transmissive material to ensure that the second alignment mark is optically visible.

The second alignment mark 23 may be generated before the process of generating the bank, and then the bank 21 is directly generated at the position corresponding to the second alignment mark 23 during the process of generating the banks so that the bank 21 covers the second alignment mark 23.

The bank or the light-transmissive material may completely or partially cover the second alignment mark, that is, the bank or the light-transmissive material at least partially overlaps the orthographic projection of the second alignment mark on the display panel. The definition of the word “cover” in other embodiments of the present disclosure is the same and is not repeated.

At least one first alignment mark and at least one second alignment mark are provided in the display panel without excessive limitations.

In some embodiments, as shown in FIGS. 5 to 8, the light-shielding layer 11 and the banks 21 are located on a side of the driver layer 200 facing away from the substrate 100, and the first alignment mark 22 or the second alignment mark 23 is both located on the driver layer 200.

In an embodiment, after the light-shielding material is used to form the light-shielding layer, an etching process is used to remove part of the excess light-shielding material. However, as shown in FIGS. 5 to 8, the alignment mark is located on the driver layer on a lower film in the display panel; if the material of the light-shielding layer overflows to the position of the alignment mark, the material is difficult to remove through etching. Therefore, the alignment mark needs to be protected using the schemes of the preceding embodiments.

The bank is provided before the light-shielding layer is formed to directly prevent the material of the light-shielding layer from overflowing to the alignment mark; or the light-transmissive bank or the light-transmissive material is used to cover the alignment mark so that even if the material of the light-shielding layer overflows to the corresponding position of the alignment mark, the material of the light-shielding layer covers only the top of the light-transmissive material on a higher film and can be removed later through etching.

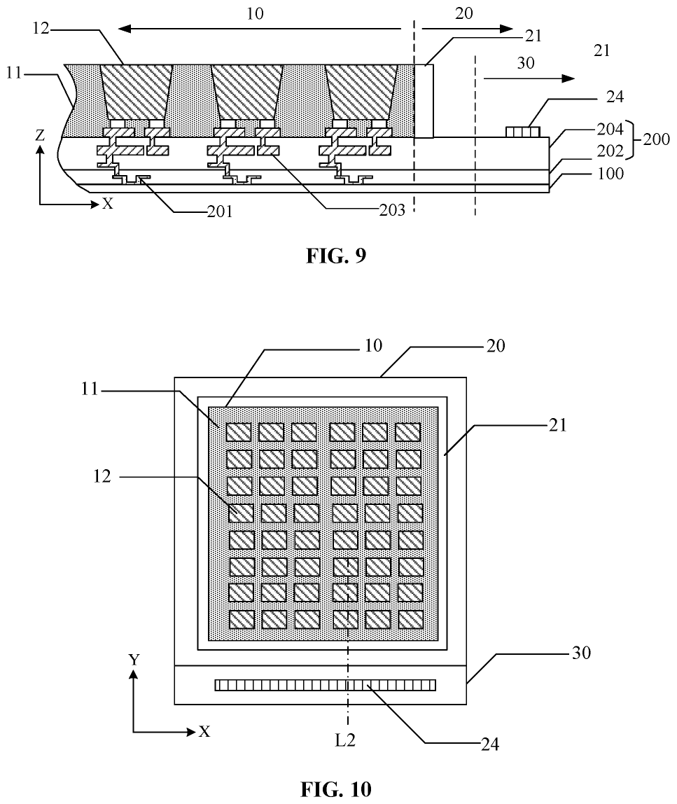

In some embodiments, as shown in FIGS. 9 and 10 (FIG. 10 is a schematic diagram of the overall planar structure of a display panel, and FIG. 9 is a partial cross-sectional view of a display panel taken along a cutting line L2 in FIG. 10), the non-display region 20 further includes a bonding region 30, and in the bonding region 30, the display panel includes multiple pins 24; and the bank 21 is located between the display region 10 and the bonding region 30.

The pins are configured to connect the display panel to an external circuit. The external circuit provides drive signals for the display panel through the pins, thereby driving the display panel to display. To ensure that the pins can be connected to the external circuit normally, the bank needs to be provided between the display region and the bonding region to prevent the material of the light-shielding layer from overflowing to the pins.

In an embodiment, the bonding region 30 may further include a flexible printed circuit (FPC) board, an integrated circuit (IC) chip, and the alignment mark in the preceding embodiments.

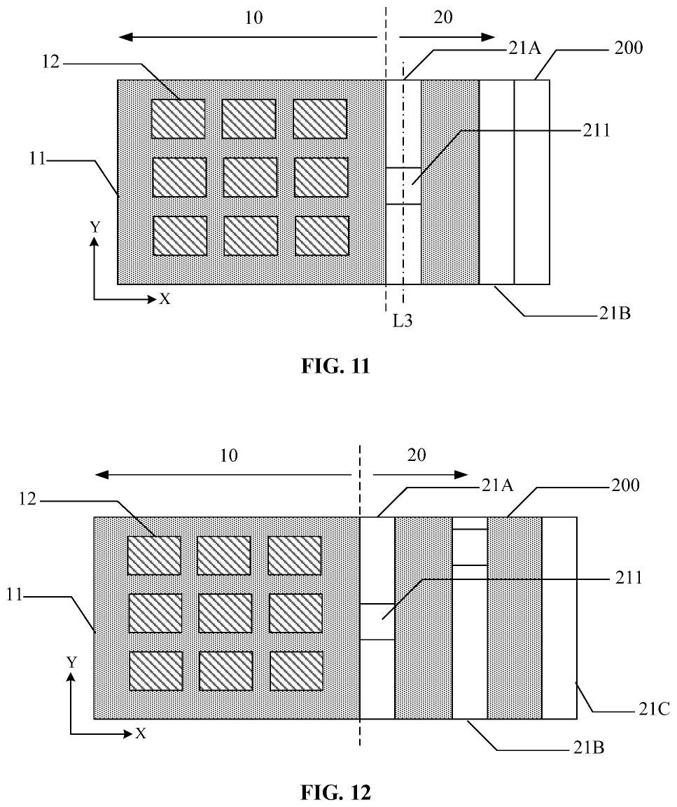

In some embodiments, as shown in FIG. 11, the bank 21 includes a first bank 21A and a second bank 21B, the first bank 21A is located on a side of the second bank 21B facing the display region, the first bank 21A includes a gap 211, and the gap 211 communicates with two opposite sides of the first bank 21A.

Since carbon black or black pigment is added to the material of the light-shielding layer 11, the adhesion between the material of the light-shielding layer and the display panel is reduced. The gap is added in the internal bank to connect the material of the light-shielding layer on two sides of the bank so that the material of the light-shielding layer between the banks can improve the adhesion to the display panel through the light-shielding layer in the display region, thereby avoiding the warping of the material of the light-shielding layer between the banks in a large-dimension display panel.

As shown in FIG. 12, in the case where the display panel includes multiple banks, except for a bank 21C closest to the cutting edge, the bank 21A and the bank 21B that are located internally may each include the gap 211. Moreover, to prevent too much material of the light-shielding layer from overflowing directly from the gap, a distance difference exists between the gaps on different banks in the Y direction in the figure. The X direction is from the display region to the non-display region, and the Y direction intersects with the X direction.

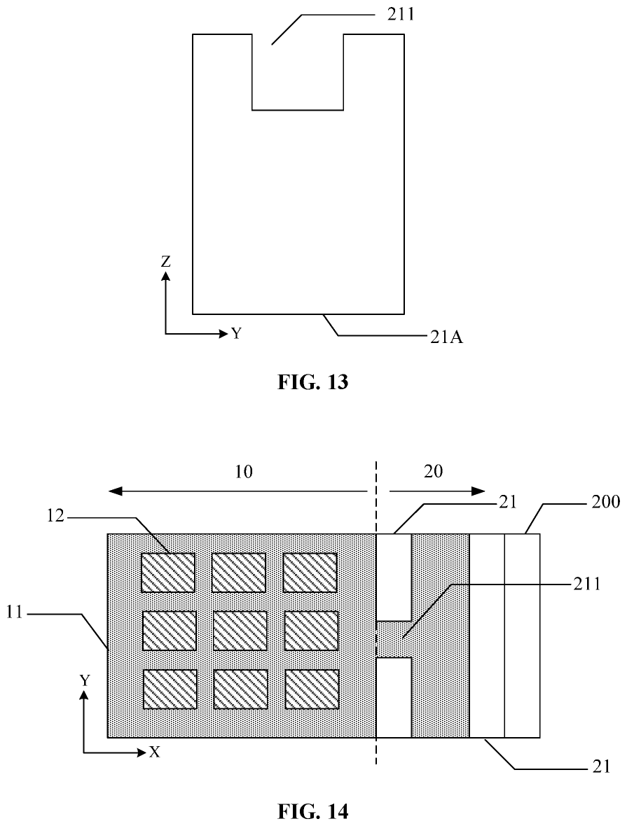

Alternatively, as shown in FIG. 13 (FIG. 13 is a partial cross-sectional view of a bank taken along a cutting line L3 in FIG. 11), the gap 211 may be located at the top of the bank and formed through etching.

In an embodiment, as shown in FIG. 14, the gap 211 and the transparent bank where the gap 211 is located have the same depth in the thickness direction Z and the same width in the first direction X, that is, the gap 211 is at the break point of the bank 21 and may be formed through etching.

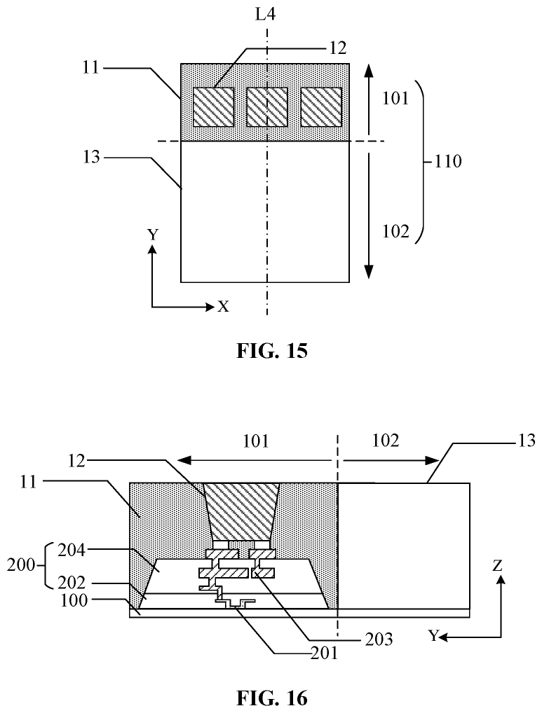

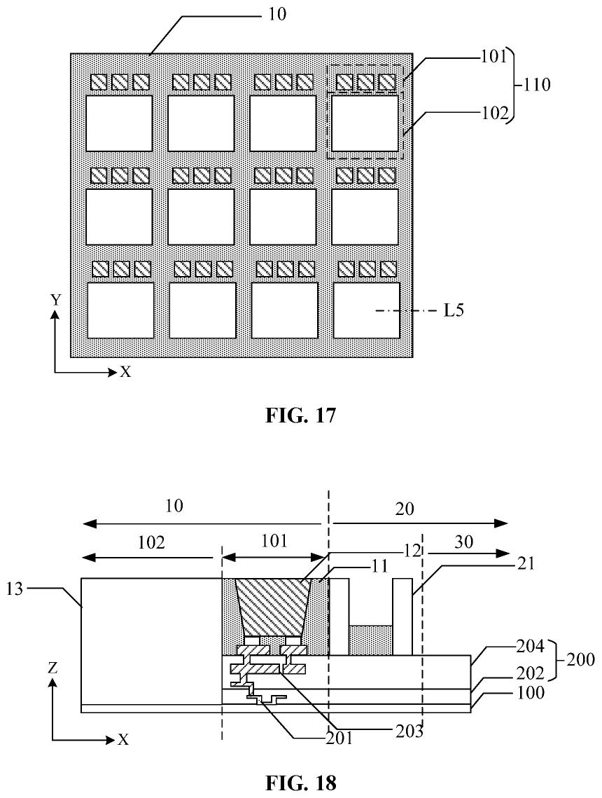

In some embodiments, as shown in FIGS. 15 to 17, the display region 10 includes multiple pixel regions 110. FIG. 15 is a top diagram of one pixel region 110, FIG. 16 is a cross-sectional view of the pixel region 110 in FIG. 15 taken along a cutting line L4, and FIG. 17 is a top diagram of part of a display panel including multiple pixel regions 110.

One pixel region 110 includes a device region 101 and a transparent region 102. In the device region 101, the display panel includes the driver layer 200, the driver layer 200 includes multiple films, and at least one film in the multiple films is cut off in the transparent region 102; in the transparent region 102, the display panel includes a filling portion 13; and the light-shielding layer 11 includes a part located in the device region 101 and the light-shielding layer 11 is in contact with the filling portion 13. The device region 101 may further include the light-emitting elements 12 located on a side of the driver layer 200 facing away from the substrate 100. Multiple light-emitting elements 12 may be provided in one pixel region 110. For example, a red light-emitting element 12, a green light-emitting element 12, and a blue light-emitting element 12 may be separately provided in one pixel region 110 to achieve color display.

In the transparent display panel technology, the transparent region is disposed in the display region so that the light behind the display panel can penetrate the display panel and be perceived by human eyes in front of the display panel, thereby achieving a transparent display effect. Since a driver circuit (including multiple thin-film transistors) for driving the light-emitting elements to emit light needs to be provided in the films of the device region, the films in the device region cannot achieve light transmission. In the transparent region 102, no driver circuit is provided to satisfy the light transmission requirement of this region. In addition, at least one film in the device region is cut off in the transparent region so that the number of stacked films in the transparent region is reduced, thereby reducing the optical loss caused by the interfaces of multiple films and improving the transmittance of the transparent region 102. The driver layer 200 of the device region 101 includes the first insulating layer 202, the metal layer 203, and the second insulating layer 204. At least one of the first insulating layer 202, the metal layer 203, or the second insulating layer 204 is cut off in the transparent region 102.

The preceding substrate 100 is a light-transmissive glass substrate, and the material of the filling portion 13 includes a light-transmissive material. In the embodiment shown in FIG. 16, all films of the driver layer 200 in the device region 101 are cut off in the transparent region 102. In another embodiment, the transparent region 102 may further include the second insulating layer 204 extending from the device region 101.

In some embodiments, as shown in FIG. 18, the upper surface of the light-shielding layer 11 is flush with the upper surface of the filling portion 13, and the upper surface of the filling portion 13 is flush with the upper surface of the bank 21 in the preceding embodiments.

The upper surface of the filling portion 13 is also flush with the upper surface of the light-emitting element 12. Since the light-emitting element 12 has a certain thickness, at least part of the films in the device region 101 is cut off in the transparent region 102, resulting in a relatively large step difference between the light-emitting element 12 and the surface of the transparent region before the filling portion 13 is generated. The thickness of the driver layer 200 located in the device region 101 is about 6 μm, and the height of the light-emitting element 12 is about 10 μm. Before the filling portion 13 is formed, the step difference between the surface of the glass substrate 100 and the upper surface of the light-emitting element 12 in the transparent region 102 is about 10 to 16 μm. The filling portion 13 bridges the step difference, which is conducive to subsequently filling the light-shielding material into the device region 101 to form the light-shielding layer 11, thereby forming a structure in which the upper surface of the light-shielding layer 11 is flush with the upper surface of the filling portion 13. Moreover, since the bank in the preceding embodiments is flush with the upper surface of the light-emitting element, the upper surface of the filling portion is also flush with the upper surface of the bank in the preceding embodiments, so as to form a planarization surface of the display panel.

In some embodiments, as shown in FIG. 18, the width of the bank 21 in the preceding embodiments is less than the width of the filling portion 13. The filling portion is mainly used for achieving a transparent display, and the length and width of the filling portion are slightly greater than the length and width of the bank playing the blocking role, thereby maximizing the light transmittance. The width may refer to the width in the X direction.

In an embodiment, the material of the filling portion 13 and the material of the bank 21 in the preceding embodiments are the same and are both the light-transmissive material. The filling portion 13 and the bank 21 in the preceding embodiments may be formed in the same process through the same technique.

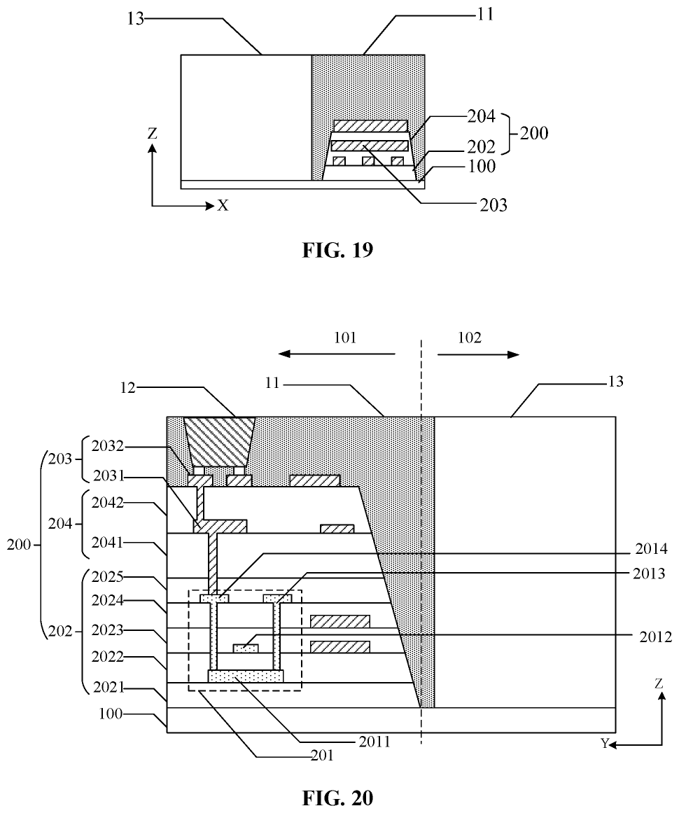

In an embodiment, as shown in FIG. 17, in the display panel, the region between the transparent regions 102 of two pixel regions 110 also includes the light-shielding layer 11. Moreover, as shown in FIG. 19 (FIG. 19 is a cross-sectional view of a display panel shown in FIG. 17 taken along a cutting line L5), the driver layer 200 in the region between the transparent regions 102 of two pixel regions 110 includes the metal layer 203, and the metal layer 203 forms signal wires of the pixel regions 110.

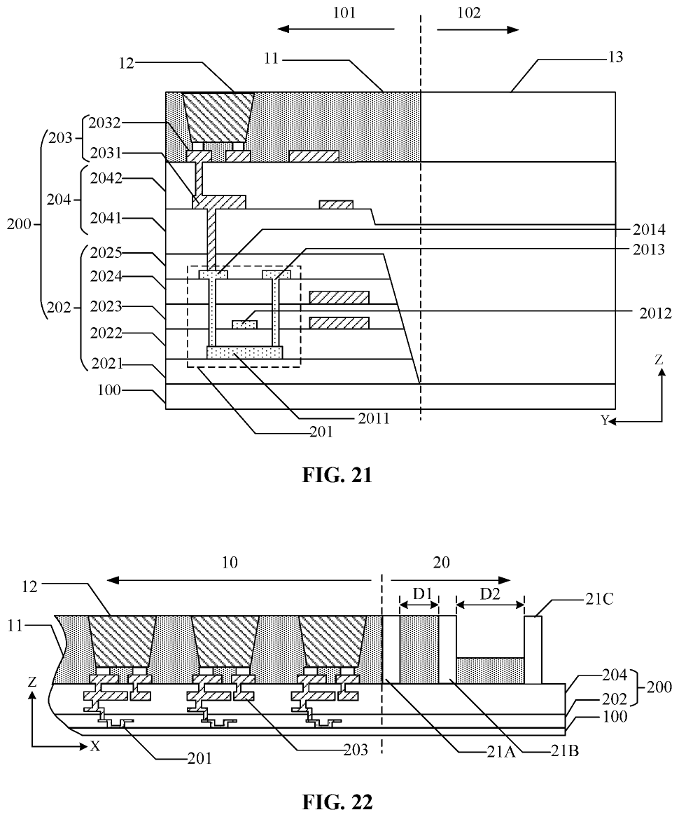

The present disclosure further provides more embodiments to illustrate the film structure of the display panel. In the embodiment shown in FIGS. 20 and 21, the display panel includes the glass substrate 100, a buffer layer (Buffer) 2021, a gate insulating layer (GI) 2022, an interlayer dielectric insulating layer (IMD) 2023, an interlayer dielectric layer (ILD) 2024, a passivation layer (PV) 2025, a first planarization layer (PLN) 2041, and a second planarization layer 2042 that are stacked in sequence in the device region 101. The buffer layer 2021, the gate insulating layer 2022, the interlayer dielectric insulating layer 2023, the interlayer dielectric layer 2024, and the passivation layer 2025 may be used as the first insulating layer 202 in the preceding embodiments, and the first planarization layer 2041 and the second planarization layer 2042 may be used as the second insulating layer 204 in the preceding embodiments.

The display panel further includes the thin-film transistors 201 located in the first insulating layer 202 in the device region 101. As shown in FIGS. 20 and 21, the thin-film transistor 201 includes an active layer 2011, a gate 2012, a source 2013, and a drain 2014. In another embodiment, the thin-film transistor 201 includes an active layer 2011, a gate 2012, a drain 2013, and a source 2014.

In the device region 101, the display panel further includes a first metal layer 2031 located in the second insulating layer 204 and a second metal layer 2032 located on a side of the second insulating layer 204 facing away from the substrate. The light-emitting element 12 is bonded to the second metal layer 2032, and the light-shielding layer 11 surrounds the light-emitting element 12 bonded to the second metal layer 2032.

In the embodiment shown in FIG. 20, the transparent region 102 includes only the glass substrate 100 and the filling portion 13 made of the light-transmissive material. In the embodiment shown in FIG. 21, the transparent region 102 includes the glass substrate 100 and the filling portion 13 made of the light-transmissive material and further includes the first planarization layer 2041 and the second planarization layer 2042 extending from the device region 101.

In some embodiments, as shown in FIG. 22, the bank 21 includes the first bank 21A, the second bank 21B, and a third bank 21C arranged at intervals in sequence along the first direction X, and the distance D1 between the first bank 21A and the second bank 21B is less than the distance D2 between the second bank 21B and the third bank 21C. That is, in the embodiment in which the display panel includes multiple banks, the distance between two banks increases in sequence from the display region to the non-display region.

On the basis of providing multiple banks, the area proportion and boundary of the overflowing material of the light-shielding layer are increased so that the visual difference between the display region and the non-display region can be improved and the adhesion of the material of the light-shielding layer to the display panel can be improved.

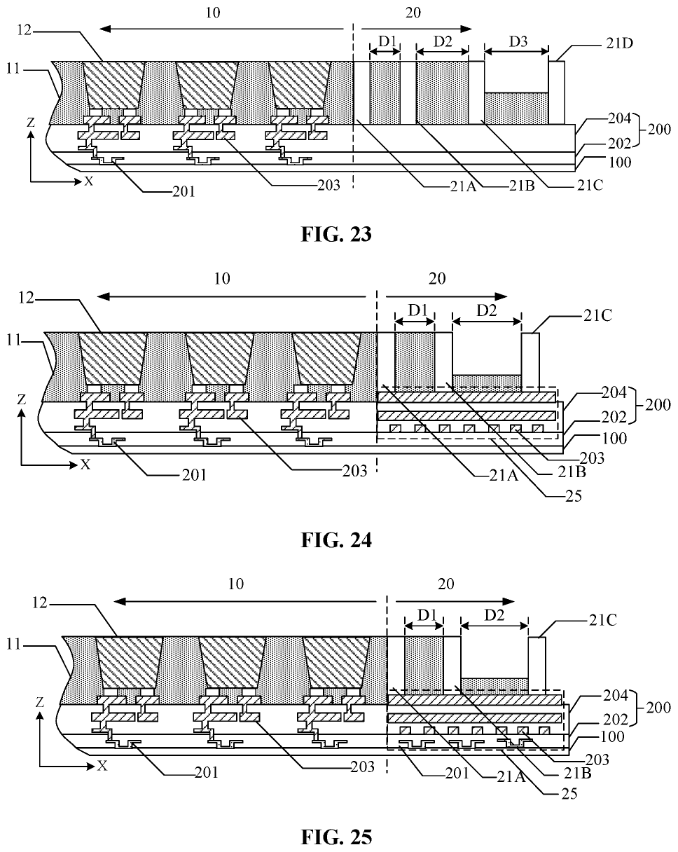

In another embodiment, as shown in FIG. 23, the bank 21 includes the first bank 21A, the second bank 21B, the third bank 21C, and a fourth bank 21D arranged at intervals in sequence along the first direction X, the distance D1 between the first bank 21A and the second bank 21B is less than the distance D2 between the second bank 21B and the third bank 21C, and the distance D2 between the second bank 21B and the third bank 21C is less than the distance D3 between the third bank 21C and the fourth bank 21D.

Those skilled in the art can deduce the bank distance relationship of a larger number of banks based on the embodiments of FIGS. 22 and 23, and the details are not repeated.

In the embodiments in which multiple banks 21 are provided, the distances between the banks 21 may be configured to be the same.

In some embodiments, as shown in FIG. 24, in the non-display region 20, the driver layer 200 further includes a peripheral driver circuit 25, and the bank 21 overlaps the peripheral driver circuit 25. The display panel further includes pixels in the display region 10. The pixel includes the light-emitting element and a pixel circuit. The peripheral circuit is configured to provide a driving control signal for the pixel, such as a scan signal and a light emission control signal.

The peripheral driver circuit includes the metal layer, and the metal layer has greater reflectivity. While the banks are formed above the peripheral driver circuit, the distance between two banks increases in sequence along the direction from the display region to the non-display region so that the area of the metal layer of the peripheral driver circuit covered by the material of the light-shielding layer can be increased, the reflectivity of the peripheral driver circuit in the non-display region can be reduced, and the visual effect at the corresponding position of the peripheral driver circuit in the non-display region can be improved.

The preceding peripheral driver circuit is disposed on at least one side of the display region. In the case where the number of pixels in the display region is relatively small, the driver circuit may be disposed on one side to achieve unilateral driving; in the case where the number of pixels in the display region is relatively large, the driver circuit may be disposed on two opposite sides of the display region to achieve bilateral driving; if necessary, the driver circuits may be disposed around the display region, without excessive limitations here.

In an embodiment, the peripheral driver circuit 25 may include only the metal layer 203 located in the second insulating layer 204 as shown in FIG. 24 or may include both the metal layer 203 located in the second insulating layer 204 and the thin-film transistors 201 located in the first insulating layer 202 as shown in FIG. 25, which can be set by those skilled in the art according to the functional requirements of the peripheral driver circuit during implementation, without excessive limitations here.

In some embodiments, as shown in FIGS. 22 and 23, the width of the first bank 21A, the width of the second bank 21B, and the width of the third bank 21C are substantially the same, that is, the difference between the width of the first bank 21A, the width of the second bank 21B, and the width of the third bank 21C is within the process error range.

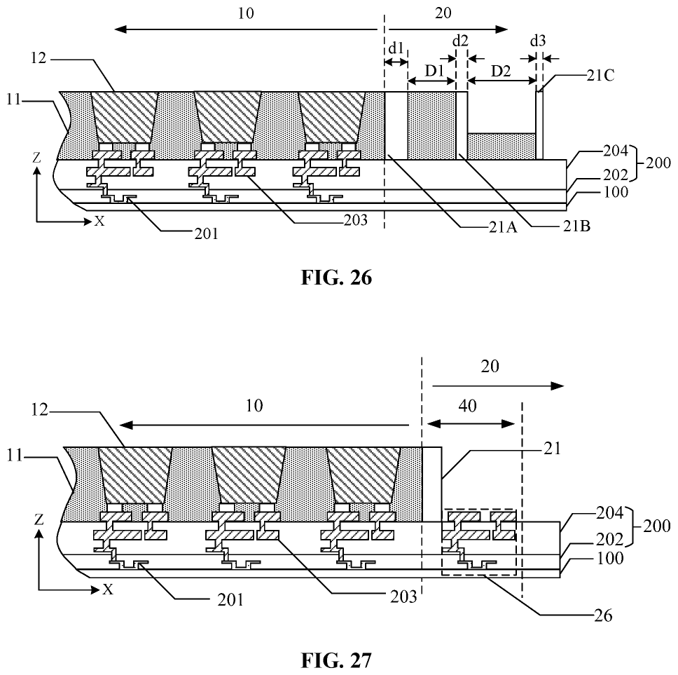

In other embodiments, as shown in FIG. 26, the width d2 of the second bank 21B is less than the width d1 of the first bank 21A, and the width d3 of the third bank 21C is less than the width d2 of the second bank 21B, that is, the width of the bank decreases in sequence along the direction from the display region to the non-display region. In this embodiment, a gradual increase in the distance between two banks can be achieved by gradually reducing the width of the bank.

In some embodiments, as shown in FIG. 27, the non-display region 20 further includes a virtual pixel region 40, the virtual pixel region 40 is adjacent to the display region 10, and in the virtual pixel region 40, the display panel includes a virtual pixel 26 and the bank 21.

Virtual pixels are usually disposed around regular pixels in the display region. The internal circuit structure of the virtual pixel is the same as that of the regular pixel, and the virtual pixel only plays a role in matching the regular pixel. For example, the virtual pixel may be used to generate the reference voltage required by the regular pixel so that a reference voltage generation circuit occupying the area of the display panel does not need to be provided separately. Since no light-emitting element needs to be provided on the virtual pixel, the bank in the preceding embodiments can be provided in the region of the virtual pixels while the virtual pixels match the regular pixels so that too much additional area in the non-display region does not need to be occupied.

For the film structure of the virtual pixel, reference may be made to the structure in the device region 101 except for the light-emitting element shown in FIGS. 20 and 21. Moreover, in different implementation scenarios, the film structure of the virtual pixel may or may not include the thin-film transistor 201, without excessive limitations here.

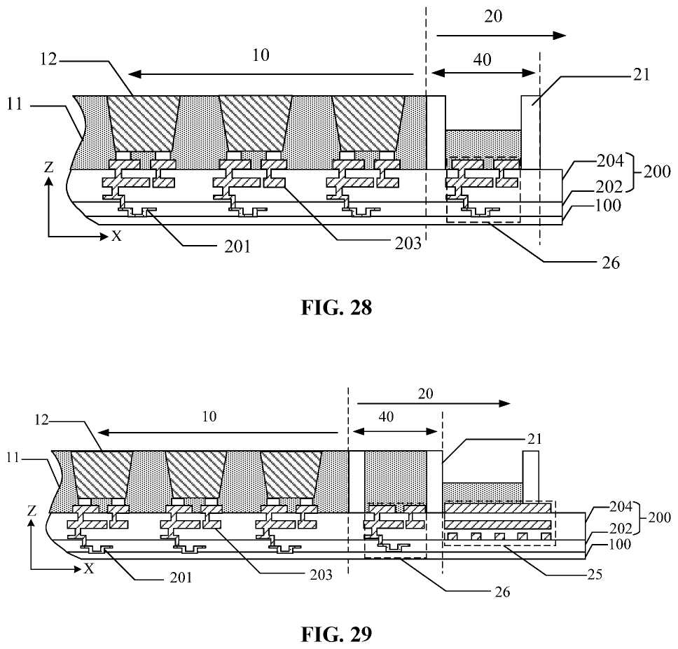

In some embodiments, as shown in FIG. 28, the display panel includes at least two banks, the space between two adjacent banks forms the overflow groove, and the overflow groove overlaps the virtual pixels. The overflow groove may partially overlap or completely overlap the virtual pixel.

Since the virtual pixel is not bonded to the light-emitting element, the metal layer on the upper surface of the virtual pixel is exposed and has greater reflectivity; and the overflow groove overlaps the virtual pixel so that the overflowing light-shielding material can be used to cover the virtual pixel, the reflectivity of the metal layer can be reduced, and the visual effect of the virtual pixel region can be improved.

In an embodiment, on the basis of the overflow groove overlapping the virtual pixel, the width of the bank may decrease in sequence along the direction from the display region to the non-display region, so as to achieve the sequential increase in the distance between two banks in the preceding embodiments along the direction from the display region to the non-display region, thereby achieving the beneficial effects of the corresponding embodiments.

In an embodiment, as shown in FIG. 29, in part of the non-display region 20, the display panel includes both the peripheral driver circuit 25 and the virtual pixel 26. The virtual pixel 26 is located on a side of the peripheral driver circuit 25 facing the display region 10.

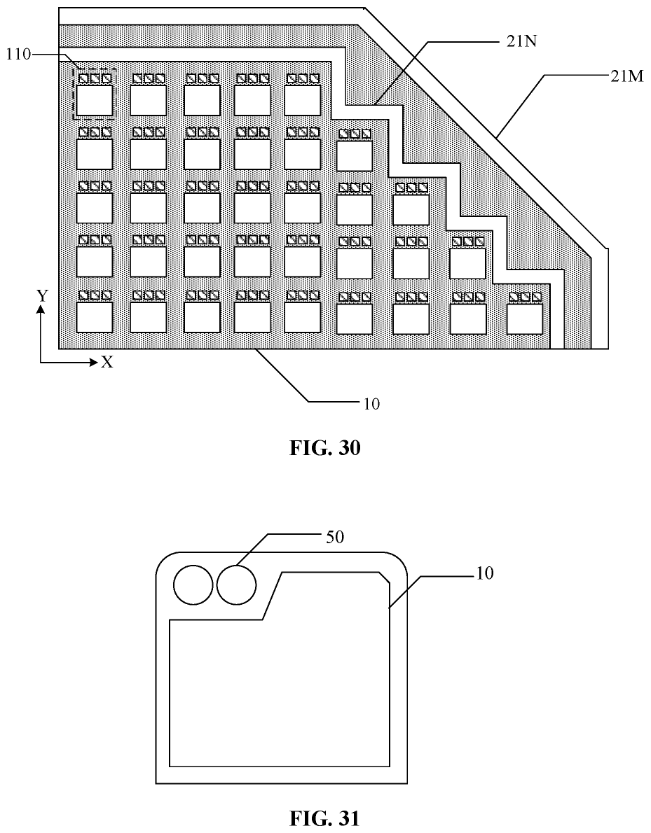

In some embodiments, as shown in FIG. 30, the display panel further includes an irregular region. In the irregular region, the display region 10 includes a serrate edge, the bank includes a fourth bank 21N and a fifth bank 21M, and the fourth bank 21N is located on a side of the fifth bank 21M facing the display region 10.

The fourth bank 21N is serrate and matches the serrate edge of the display region 10. The fifth bank 21M includes a straight line segment, and along an arrangement direction of the fifth bank 21M and the fourth bank 21N, the straight line segment of the fifth bank 21M covers multiple sawteeth in the fourth bank 21N.

In the related art, some smart devices have irregular shapes to match a camera, another component region, or the edge of the display device, for example, a circular display device or a rounded rectangular display device has an edge of an irregular shape. FIG. 31 shows an electronic device including a display region 10 and a camera 50. It can be seen that to match the camera 50, the display region 10 has an irregular special-shaped design.

The irregularity of the display region is usually caused by different cut-off positions of pixel rows and is visually reflected as the serrate edge. To make the material of the light-shielding layer at different positions of the display panel evenly filled, the bank closer to the display region needs to be designed according to the serrate edge of the display region. However, the serrate bank has relatively large process difficulty, the bank closer to the cutting edge directly uses a straight edge design so that the bank can block the material of the light-shielding layer; and at the same time, the process difficulty is reduced and the manufacturing process is simplified.

In an embodiment, the fourth bank covers the second alignment mark in the preceding embodiments, and the fifth bank is located at a position of the first alignment mark in the preceding embodiments facing the display region.

Since the second alignment mark is configured to determine the position of the light-emitting element or pixel in the display region during the problem-solving analysis of the display panel, the second alignment mark needs to be located at a position in the non-display region relatively close to the display region, and the position corresponds to pixels in each row/column. In this case, the bank matching the edge of the display region needs to cover and protect the second alignment mark.

Since the first alignment mark is configured to align the entire display panel with the external device and is located on the outer side of the display panel, the bank can be disposed at any position of the first alignment mark facing the display region. Therefore, the fifth bank may directly use a straight edge design so that the process difficulty is reduced and the manufacturing process is simplified.

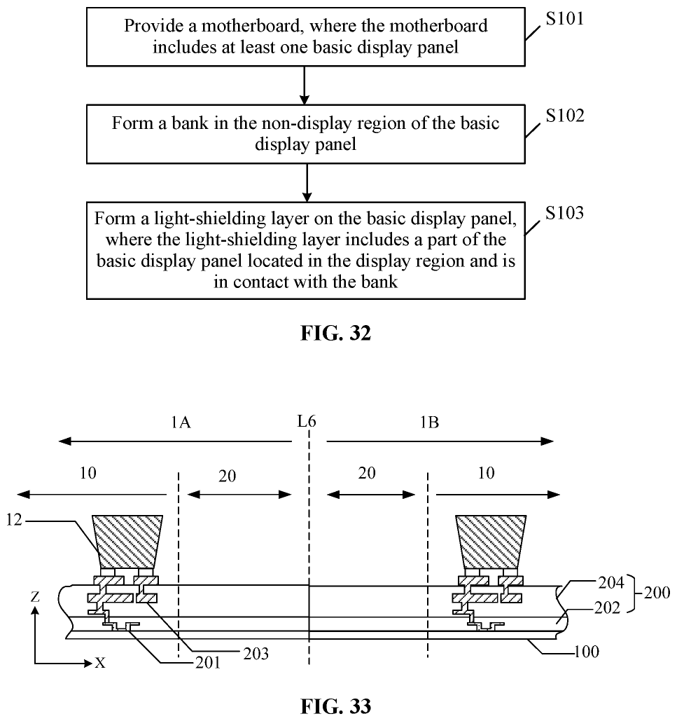

Based on the same concept, an embodiment of the present disclosure further provides a manufacturing method of a display panel. As shown in FIG. 32, the method includes the steps described below.

In S101, a motherboard is provided, where the motherboard includes at least one basic display panel.

The embodiment of FIG. 33 shows a motherboard including two basic display panels (a first basic display panel 1A and a second basic display panel 1B). Those skilled in the art can determine the manufacturing method corresponding to the motherboard including one basic display panel based on the embodiment of FIG. 33. The details are not repeated in the embodiment below. Each basic display panel includes the display region 10 and the non-display region 20, and the non-display regions 20 of two basic display panels are adjacent.

In an embodiment, as shown in FIG. 33, the basic display panel further includes the light-emitting elements 12, the substrate 100, and the driver layer 200. The driver layer 200 is located on the substrate 100 and includes multiple thin-film transistors 201 corresponding to the light-emitting elements 12 as well as the first insulating layer 202, the metal layer 203, and the second insulating layer 204. The light-emitting elements 12 are bonded to the metal layer 203 and electrically connected to the thin-film transistors 201 through the metal layer 203. For the structure of the basic display panel, reference may be made to the preceding embodiments of the display panel, and the details are not repeated here.

In S102, a bank is formed in the non-display region of the basic display panel.

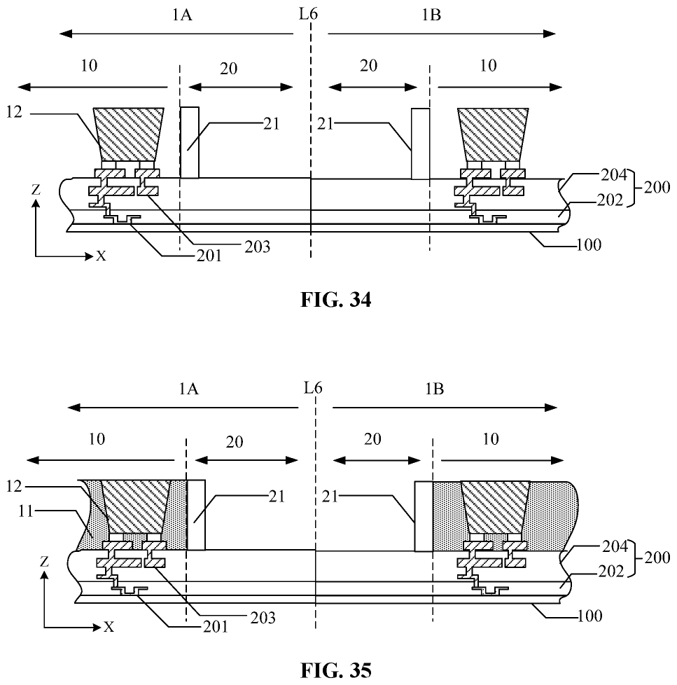

The basic display panel in which the bank 21 is formed is shown in FIG. 34.

In S103, a light-shielding layer is formed on the basic display panel, where the light-shielding layer includes a part located in the display region and is in contact with the bank.

The basic display panel in which the light-shielding layer 11 is formed is shown in FIG. 35.

In the display panel provided in the embodiments of the present disclosure, through the bank, the light-shielding material can be blocked and confined to the display region so that the light-shielding material does not further overflow to the region outside the display region, thereby ensuring smooth subsequent processes and cutting.

In some embodiments, as shown in FIGS. 33 to 35, the motherboard includes at least two basic display panels, and the non-display regions 20 of the two basic display panels are adjacent. FIGS. 33 to 35 illustrate the first basic display panel 1A and the second basic display panel 1B.

After S103, the preceding method further includes the steps described below.

In S104, an adjacent part of every two basic display panels in the motherboard is cut to obtain at least two display panels.

In the embodiments shown in FIGS. 33 to 35, cutting the adjacent part of every two basic display panels in the motherboard includes cutting two basic display panels along L6.

In the display panel provided in the embodiments of the present disclosure, through the bank, the light-shielding material can be blocked and confined to the display region so that the light-shielding material does not further overflow to the region where the cutting edge is located (that is, the preceding adjacent part of two basic display panels), so as to prevent the light-shielding material from adhering to a cutting wheel or from affecting the cutting laser transmittance, thereby ensuring smooth subsequent processes and cutting.

In some embodiments, S102 includes the steps described below.

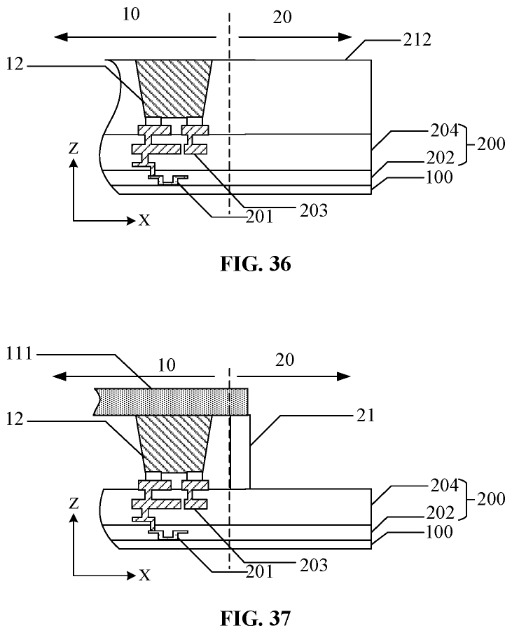

In S201, as shown in FIG. 36, a transparent film 212 is formed on the basic display panel.

The transparent film 212 surrounds the light-emitting elements. For the material of the transparent film, reference may be made to the light-transmissive material in the preceding embodiments, and the details are not repeated here.

In S202, a mask plate is used to perform mask exposure on the transparent film.

The pattern of the mask plate corresponds to the position of the bank that needs to be generated.

In S203, reactive etching is performed on the transparent film after the mask exposure to form the bank.

The reactive etching process includes ashing. Those skilled in the art can use other processes to remove the transparent film except the bank, without excessive limitations here.

In an embodiment, as shown in FIGS. 15 to 18, the display region includes multiple pixel regions 110. One pixel region 110 includes the device region 101 and the transparent region 102. In the device region 101, the display panel includes the driver layer 200, the driver layer 200 includes multiple films, and at least one film in the multiple films is cut off in the transparent region 102. S201 includes the step described below.

The transparent film 212 is formed in the transparent region of the basic display panel to form the filling portion 13 shown in FIGS. 15 to 18.

In some embodiments, S103 includes the step described below.

In S301, the light-shielding material is filled into the basic display panel through a compression molding process or a thermoplastic molding process.

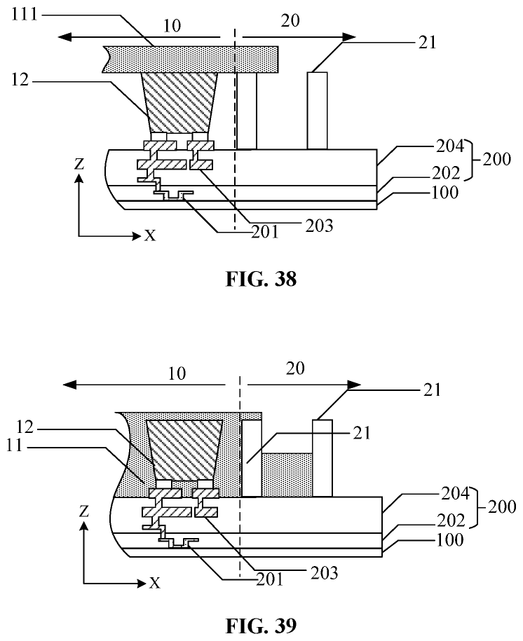

As shown in FIG. 37, the light-shielding material includes a compression molded film 111 pre-cut according to the dimension of the display region. The dimension of the compression molded film is greater than or equal to the dimension of the display region and less than or equal to the dimension of the display panel including both the display region and the non-display region. In the case where the display panel includes multiple banks, as shown in FIG. 38, the dimension of the compression molded film may be slightly greater than the size of the display region so that the light-shielding material can be fully filled into the display region, and at the same time, the overflowing light-shielding material can be stored between the multiple banks.

The step S301 includes the following: As shown in FIG. 37, the compression molded film 111 covers the display region 10 of the display panel, and then the compression molded film 111 is processed with a preset temperature or a preset pressure for a preset time so that the compression molded film 111 is filled into the display region to form the light-shielding layer 11 in the preceding embodiments.

Since the processing parameters of compression molded films of different materials and specifications are different, those skilled in the art may set corresponding parameters according to the instructions for use of different compression molded films. Therefore, no excessive limitations are made on the preset temperature, the preset pressure, and the preset time.

Although in the related art, the light-shielding material can be filled into the display region through photolithography or ink printing, compared with the compression molding process or the thermoplastic molding process, the photolithography manner requires more mask plates, the production cost is increased, and the etching angle, thickness, resolution, and light absorbance of the light-shielding material are all unsatisfactory; the uniformity of ink printing is relatively poor, the obvious color cast exists at a large viewing angle, bubbles are easily formed at the bottom of the light-emitting element, and the effect is also unsatisfactory.

During implementation, as shown in FIG. 39, after the light-shielding material (that is, the preceding compression molded film) is filled into the basic display panel to form the light-shielding layer 11, the light-shielding material remains on at least part of the bank 21. Therefore, after S301, the preceding method further includes etching the light-shielding layer 11 to remove at least part of the thickness of the light-shielding layer 11 until no residual light-shielding material exists on the surface of the bank 21 or until the light-shielding layer 11 is flush with the light-emitting element 12 and the bank 21 in height (as shown in FIG. 35).

In an embodiment, the etching process includes ashing.

Based on the same inventive concept, corresponding to the display panel in any of the preceding embodiments, an embodiment of the present disclosure further provides a display device including the display panel in any of the preceding embodiments.

The display device provided in the embodiment of the present disclosure may be any product or component having a display function, such as a mobile phone, a tablet computer, a television, a display, a laptop, a digital photo frame, or a navigator.

The display device in the preceding embodiment includes the corresponding display panel in any of the preceding embodiments and has the beneficial effects of the corresponding embodiments. The details are not repeated here.

It is to be noted that herein, relationship terms such as “first” and “second” are used merely for distinguishing one entity or operation from another and do not necessarily require or imply any such actual relationship or order between these entities or operations. Furthermore, the term “comprising”, “including”, or any other variant thereof is intended to encompass a non-exclusive inclusion so that a process, method, article, or device that includes a series of elements not only includes the expressly listed elements but also include other elements that are not expressly listed or are inherent to such a process, method, article, or device. In the absence of more restrictions, the elements defined by the statement “including a . . . ” do not exclude the presence of additional identical elements in the process, method, article, or device that includes the preceding elements.

The preceding are the embodiments of the present disclosure to enable those skilled in the art to understand or implement the present disclosure. Various modifications made to these embodiments are apparent to those skilled in the art, and the general principles defined herein may be implemented in other embodiments without departing from the spirit or scope of the present disclosure. Therefore, the present disclosure is not limited to the preceding embodiments described herein but is in accord with the widest scope consistent with the principles and novel features disclosed herein.

What is claimed is:

1. A display panel, comprising a display region and a non-display region;
wherein the display panel comprises:
a light-shielding layer comprising a part located in the display region; and
a bank located in the non-display region, wherein the bank is in contact with the light-shielding layer.

2. The display panel of claim 1, wherein a material of the bank comprises a light-transmissive material.

3. The display panel of claim 1, wherein a sidewall included angle of the bank is in a range between 85° and 95°, wherein the sidewall included angle is an included angle between a sidewall of the bank and a bottom surface of the bank.

4. The display panel of claim 1, further comprising a light-emitting element;
wherein the light-emitting element is located in the display region, and the light-shielding layer surrounds the light-emitting element; and
an upper surface of the bank is flush with an upper surface of the light-emitting element.

5. The display panel of claim 2, further comprising an alignment mark,
wherein the alignment mark comprises a first alignment mark located on a side of the bank facing away from the display region; or wherein the alignment mark comprises a second alignment mark, wherein the bank covers the second alignment mark.

6. The display panel of claim 5, further comprising a substrate and a driver layer;
wherein the driver layer is located on the substrate and comprises a plurality of thin-film transistors and the alignment mark; and
the light-shielding layer and the bank are located on a side of the driver layer facing away from the substrate.

7. The display panel of claim 1, wherein the bank comprises a first bank and a second bank, wherein the first bank is located on a side of the second bank facing the display region, the first bank comprises a gap, and the gap connects with two opposite sides of the first bank.

8. The display panel of claim 1, wherein the display region comprises a plurality of pixel regions, and a pixel region of the plurality of pixel regions comprises a device region and a transparent region, wherein in the device region, the display panel comprises a driver layer, the driver layer comprises a plurality of films, and at least one film in the plurality of films is cut off in the transparent region; and in the transparent region, the display panel comprises a filling portion;
the light-shielding layer comprises a part located in the device region and the light-shielding layer is in contact with the filling portion; and
a material of the filling portion is the same as a material of the bank.

9. The display panel of claim 8, wherein an upper surface of the light-shielding layer is flush with an upper surface of the filling portion; and
the upper surface of the filling portion is flush with an upper surface of the bank.

10. The display panel of claim 8 wherein a width of the bank is less than a width of the filling portion.

11. The display panel of claim 1, wherein the bank comprises a first bank, a second bank, and a third bank that are arranged at intervals in sequence along a first direction, wherein an interval between the first bank and the second bank is less than an interval between the second bank and the third bank;
wherein the first direction is from the display region to the non-display region.

12. The display panel of claim 11, wherein a width of the first bank, a width of the second bank, and a width of the third bank are the same; or
wherein a width of the second bank is less than a width of the first bank, and a width of the third bank is less than the width of the second bank.

13. The display panel of claim 1, wherein the non-display region further comprises a virtual pixel region, wherein the virtual pixel region is adjacent to the display region, and in the virtual pixel region, the display panel comprises a virtual pixel; and
in the virtual pixel region, the display panel comprises the bank.

14. The display panel of claim 1, further comprising an irregular region,
wherein in the irregular region, the display region comprises a serrate edge, the bank comprises a fourth bank and a fifth bank, and the fourth bank is located on a side of the fifth bank facing the display region;
the fourth bank is serrate and matches the serrate edge of the display region; and
the fifth bank comprises a straight line segment, and along an arrangement direction of the fifth bank and the fourth bank, the straight line segment of the fifth bank covers a plurality of sawteeth in the fourth bank.

15. The display panel of claim 1, further comprising a substrate, a driver layer, and a light-emitting element;
wherein the driver layer is located on the substrate and comprises a plurality of thin-film transistors;
the light-emitting element is located on a side of the driver layer facing away from the substrate; and
the light-shielding layer and the bank are located on the side of the driver layer facing away from the substrate, and the light-shielding layer surrounds the light-emitting element;
wherein in the non-display region, the driver layer further comprises a peripheral driver circuit, and the bank overlaps the peripheral driver circuit.

16. The display panel of claim 1, wherein the non-display region further comprises a bonding region, and in the bonding region, the display panel comprises a plurality of pins; and
the bank is located between the display region and the bonding region.

17. A manufacturing method of a display panel, comprising:
providing a motherboard, wherein the motherboard comprises at least one basic display panel, and each of the at least one basic display panel comprises a display region and a non-display region;
forming a bank in the non-display region of each of the at least one basic display panel; and
forming a light-shielding layer on each of the at least one basic display panel, wherein the light-shielding layer comprises a part located in the display region and is in contact with the bank.

18. The manufacturing method of claim 17, wherein forming the bank in the non-display region of each of the at least one basic display panel comprises:
forming a transparent film on each of the at least one basic display panel;
performing mask exposure on the transparent film by using a mask plate; and
performing reactive etching on the transparent film after the mask exposure to form the bank;
wherein forming the light-shielding layer on each of the at least one basic display panel comprises:
filling a light-shielding material into each of the at least one basic display panel through a compression molding process or a thermoplastic molding process.

19. The manufacturing method of claim 17, wherein the motherboard comprises at least two basic display panels, and non-display regions of two of the at least two basic display panels are adjacent;
wherein after the light-shielding layer is formed on each of the at least one basic display panel, the method further comprises:
cutting an adjacent part of every two of the at least two basic display panels in the motherboard to obtain at least two display panels.

20. A display device, comprising a display panel, wherein the display panel comprises a display region and a non-display region; wherein the display panel comprises: a light-shielding layer comprising a part located in the display region; and
a bank located in the non-display region, wherein the bank is in contact with the light-shielding layer.
